(19) United States
(12) Patent Application Publication
(10) Pub. No.: US 2023/0130702 A1
(43) Pub. Date: Apr. 27, 2023

(54) INTERCONNECT STRUCTURE AND ELECTRONIC DEVICE INCLUDING THE SAME

(71) Applicant: Samsung Electronics Co., Ltd., Suwon-si (KR)

(72) Inventors: Keunwook SHIN, Suwon-si (KR); Sungtae KIM, Seoul (KR); Alum JUNG, Suwon-si (KR)

(73) Assignee: Samsung Electronics Co., Ltd., Suwon-si (KR)

(21) Appl. No.: 17/959,812

(22) Filed: Oct. 4, 2022

(30) Foreign Application Priority Data
Oct. 25, 2021 (KR) 10-2021-0143080

(51) Int. Cl. H01L 23/532

(52) U.S. Cl. CPC H01L 23/53238; H01L 23/53223; H01L 23/53266

(57) ABSTRACT

Provided are an interconnect structure and an electronic device including the same. The interconnect structure may include a first dielectric layer including a trench, a conductive wire filling an inside of trench, and a cap layer on a top surface of the conductive wire. The cap layer may include graphene doped with a group V element. A second dielectric layer may be on a top surface of the first cap layer.

### CROSS-REFERENCE TO RELATED APPLICATION

This application is based on and claims priority under 35 U.S.C. § 119 to Korean Patent Application No. 10-2021-0143080, filed on Oct. 25, 2021 in the Korean Intellectual Property Office, the disclosure of which is incorporated by reference herein in its entirety.

### BACKGROUND

### 1. Field

The present disclosure relates to an interconnect structure and an electronic device including the same.

### 2. Description of the Related Art

In recent years, the size of semiconductor devices gradually has been decreased for high integration of the semiconductor devices, and also the line width of a metal wire has been reduced due to the decrease in the size of the semiconductor device. When the line width of the metal wire is reduced, the resistivity of the metal wire may increase exponentially, and reliability may decrease due to heat generation, etc. Thus, to lower the resistance of the metal wire and secure the reliability, a cap layer may need to be provided.

### SUMMARY

Provided are an interconnect structure including a cap layer including graphene doped between a metal wire and a dielectric layer, and an electronic device including the interconnect structure.

Additional aspects will be set forth in part in the description which follows and, in part, will be apparent from the description, or may be learned by practice of the presented embodiments of the disclosure.

According to an embodiment, an interconnect structure may include a first dielectric layer including a trench, a conductive wire filling an inside of the trench, a first cap layer on a top surface of the conductive wire, and a second dielectric layer on a top surface of the first cap layer. The first cap layer may include a doped graphene. The doped graphene may be graphene doped with a group V element.

In some embodiments, a doping material of the doped graphene may include at least one of nitrogen (N), phosphorus (P), arsenic (As), or antimony (Sb).

In some embodiments, a doping concentration of the doped graphene may be about 0.1% to about 30%.

In some embodiments, the doped graphene may have a surface energy with a water contact angle of 75 degrees or less.

In some embodiments, the doped graphene may include intrinsic graphene or nanocrystalline graphene.

In some embodiments, the nanocrystalline graphene may include crystals having a size of about 0.5 nm to about 150 nm.

In some embodiments, the nanocrystalline graphene may have a thickness of 3 nm or less.

In some embodiments, the doped graphene may include a bonding structure in which a ratio of carbon having sp² bonding to total carbon is about 50% to about 99%.

In some embodiments, the conductive wire may include at least one of a metal, a metal alloy, or a combination thereof.

In some embodiments, the conductive wire may include at least one of copper (Cu), ruthenium (Ru), aluminum (Al), cobalt (Co), tungsten (W), molybdenum (Mo), titanium (Ti), tantalum (Ta), nickel (Ni), platinum (Pt), chromium (Cr), rhodium (Rh), iridium (Ir), palladium (Pd), or osmium (Os).

In some embodiments, the first dielectric layer may include a dielectric material having a dielectric constant of about 3.6 or less.

In some embodiments, the second dielectric layer may include an etch stop layer.

In some embodiments, the second dielectric layer may include a silicon carbon nitride (SiCN).

In some embodiments, the interconnect structure may further include a second cap layer in the trench and the second cap layer may include the doped graphene.

In some embodiments, the interconnect structure may further include a barrier layer in the trench.

In some embodiments, the barrier layer may cover a side surface of the conductive wire and a bottom surface of the conductive wire.

In some embodiments, the barrier layer may include a metal, a metal alloy, a metal nitride, or graphene.

In some embodiments, the barrier layer may include tantalum (Ta), titanium (Ti), ruthenium (Ru), ruthenium tantalum (RuTa), iridium tantalum (IrTa), tungsten (W), tantalum nitride (TaN), titanium nitride (TiN), ruthenium nitride (RuN), iridium tantalum nitride (IrTaN), titanium silicon nitride (TiSiN), cobalt (Co), manganese (Mn), manganese oxide (MnO), or tungsten nitride (WN).

According to an embodiment, an electronic device may include the interconnect structure.

According to an embodiment, an interconnect structure may include a first dielectric layer including a trench and a region surrounding the trench of the first dielectric layer, the region of the first dielectric layer defining a sidewall of the trench and including a top surface higher than a bottom of the trench; a conductive wire in the trench; and a first cap layer on a top surface of the conductive wire. The first cap layer may include a doped graphene. The doped graphene may include graphene doped with a group V element. The top surface of the conductive wire may be opposite the bottom of the trench.

In some embodiments, a second dielectric layer may be on the first dielectric layer. The second dielectric layer may include a first portion on the region of the first dielectric layer and a second portion over the trench of the first dielectric layer.

In some embodiments, the first dielectric layer may include silicon oxycarbide (SiOCH). The second dielectric layer may include silicon carbide (SiC).

In some embodiments, a doping concentration of the doped graphene may be about 0.1% to about 30%. The doped graphene may include intrinsic graphene or nanocrystalline graphene.

In some embodiments, the interconnect structure may include a second cap layer in the trench between first dielectric layer and the conductive wire. The second cap layer may include the doped graphene.

In some embodiments, the doped graphene of the first cap layer may be directly on the top surface of the conductive wire.

### BRIEF DESCRIPTION OF THE DRAWINGS

The above and other aspects, features, and advantages of certain embodiments of the disclosure will be more apparent from the following description taken in conjunction with the accompanying drawings, in which:

FIGS. 1 and 2 are cross-sectional views illustrating interconnect structures according to embodiments;

FIGS. 3A to 3D are cross-sectional views schematically illustrating a method of manufacturing an interconnect structure according to an embodiment;

FIGS. 4A to 4B show an example of a process of forming a cap layer including doped graphene;

FIGS. 5A to 5C show another example of a process of forming a cap layer including doped graphene;

FIG. 6 shows a comparison of analysis results of undoped graphene and graphene doped by injection of an NH₃ gas during growth;

FIG. 7A shows a water contact angle with respect to undoped graphene;

FIG. 7B shows a water contact angle change of graphene doped by injection of an NH₃ gas during the growth of the graphene;

FIG. 7C shows a water contact angle change of graphene doped by NH₃ plasma treatment after the growth of the graphene;

FIG. 8 shows a water contact angle change of graphene when the graphene is plasma-treated with an NH₃ gas after the growth of the graphene;

FIG. 9 shows a Raman spectrum indicating nanocrystalline graphene;

FIGS. 10A to 15B are cross-sectional views showing interconnect structures according to other embodiments;

FIG. 16A is a conceptual view illustrating a semiconductor device including an interconnect structure according to an example embodiment;

FIG. 16B is a conceptual view illustrating that the interconnect structure is connected to a transistor according to an example embodiment; and

FIG. 17 is a block diagram of an electronic device according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

Hereinafter, various embodiments disclosed herein will be described in detail with reference to the accompanying drawings. In the drawings, like reference numerals denote like components, and sizes of components in the drawings may be exaggerated for convenience of explanation. Meanwhile, embodiments to be described are merely examples, and various modifications may be made from such embodiments.

When an element is referred to as “on” another element, it may include not only “directly on,” “directly under” “directly on a left surface or right surface” in a contact manner, but also situations where intervening elements are present between the element and the other element (e.g., the element in a non-contact manner is on, under, at a left surface, or at a right surface of the other element). In contrast, when an element is referred to as being “directly on” or another element, there are no intervening elements present. Other words used to describe the relationship between elements or layers should be interpreted in a like fashion (e.g., “between” versus “directly between,” “adjacent” versus “directly adjacent,” “connected” versus “directly connected”, “above” versus “directly above”). Singular forms include plural forms unless apparently indicated otherwise contextually. When a portion is referred to as “comprises” a component, the portion may not exclude another component but may further include another component unless stated otherwise.

The use of the terms of “the above-described” and similar indicative terms may correspond to both the singular forms and the plural forms. When there is an explicit description of the order of operations of the method or there is no description contrary thereto, these operations may be performed in an appropriate order and the order is not necessarily limited to the described order.

The term used herein such as “unit” or “module” indicates a unit for processing at least one function or operation, and may be implemented in hardware, software, or in a combination of hardware and software.

Connections of lines or connection members between components shown in the drawings are illustrative of functional connections and/or physical or circuit connections, and in practice, may be represented as alternative or additional various functional connections, physical connections, or circuit connections.

The use of all examples or example terms is only to describe aspects of example embodiments in detail, and the scope of inventive concepts is not limited by these examples or terms unless limited by the claims.

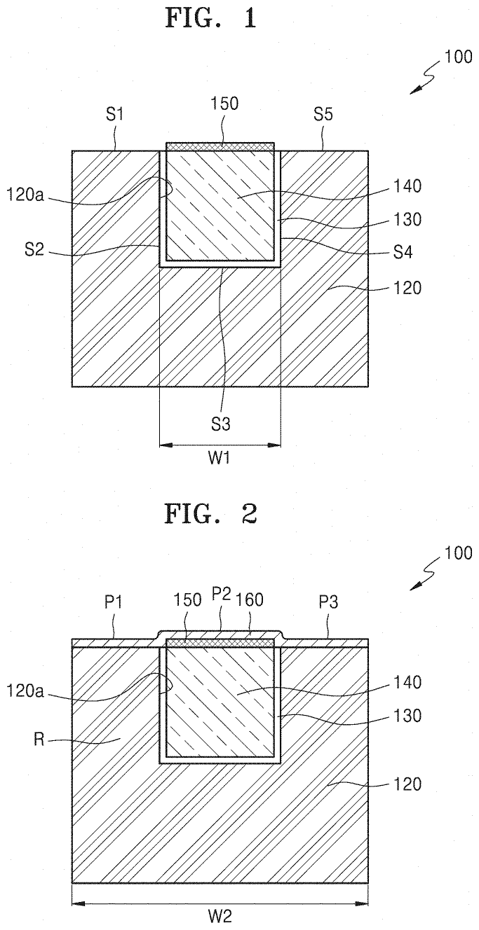

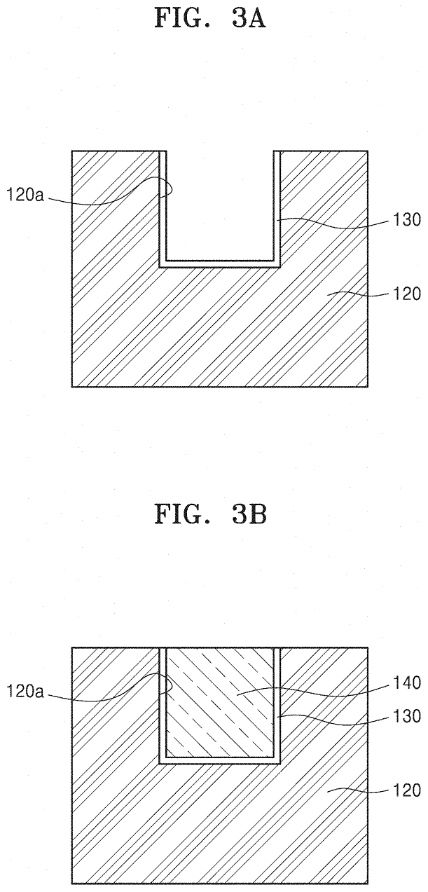

FIGS. 1 and 2 are cross-sectional views illustrating interconnect structures 100 according to embodiments. FIG. 2 shows an example in which a dielectric layer 160 is deposited on a cap layer 150 in the interconnect structure 100 of FIG. 1.

Referring to FIGS. 1 and 2, the interconnect structure 100 may include a dielectric layer 120, a conductive wire 140, and the cap layer 150. The dielectric layer 160 may be further formed on the cap layer 150. The interconnect structure 100 may be provided on a substrate (not shown), thus constituting an electronic device. For example, the electronic device may include dynamic random-access memory (DRAM), a logic element, etc., and in this case, the interconnect structure 100 may be applied to a back-end-of-line (BEOL) structure such as the DRAM, the logic element, etc. In addition, the interconnect structure 100 may be applied to various electronic devices.

The substrate may be a semiconductor substrate. For example, the substrate may include a group IV semiconductor material, a group III-V semiconductor compound, or a group II-VI semiconductor compound. That is, the substrate may include a group IV semiconductor material including at least one of silicon (Si), germanium (Ge), tin (Sn), and carbon (C), a group III-V compound semiconductor material in which at least one of boron (B), gallium (Ga), indium (In), and aluminum (Al) is combined with at least one of nitrogen (N), phosphorus (P), arsenic (As), antimony (Sb), sulfur (S), selenium (Se), and tellurium (Te), or a group II-VI compound semiconductor material in which at least one of beryllium (Be), magnesium (Mg), cadmium (Cd), and zinc (Zn) is combined with at least one of oxygen (O), S, Se, and Te. As a detailed example, the substrate may include Si, Ge, silicon carbide (SiC), silicon germanium (SiGe), silicon germanium carbide (SiGeC), a Ge alloy, gallium arsenide (GaAs), indium arsenide (InAs), indium phosphide (InP), etc. However, this is merely an example, and other various semiconductor materials may be used as a substrate.

The substrate may include, for example, a silicon-on-insulator (SOI) substrate or a silicon germanium-on-insulator (SGOI) substrate. In addition, the substrate may include an undoped semiconductor material or a doped semiconductor material.

The substrate may include at least one semiconductor element (not shown). The semiconductor element may include at least one of a transistor, a capacitor, a diode, and a resistor. However, the present disclosure is not limited thereto.

The dielectric layer 120 may be formed on the substrate. The dielectric layer 120 may have a single-layer structure or a multi-layer structure in which different materials are stacked. The dielectric layer 120 may be an intermetallic dielectric (IMD) layer. The dielectric layer 120 may include, for example, a low-k dielectric material. For example, the dielectric layer 120 may include a dielectric material having a dielectric constant of about 3.6 or less. For example, the dielectric layer 120 may include silicon oxycarbide (SiOCH), etc. However, this is merely an example, and the present disclosure is not limited thereto.

Herein, a low-k material may be a material having a dielectric constant k that is less than that of silicon oxide (SiO₂). As the size of an element decreases, a distance between the conductive wires 140 may decrease. Thus, the size of the dielectric layer 120 arranged between the conductive wires 140 decreases, resulting in a crosstalk that affects element performance. By using the low-K material for the dielectric layer 120, the parasitic capacitance affecting the performance of the device may be reduced, and a fast switching speed and low heat dissipation may be possible.

A trench 120a may be formed in the dielectric layer 120 to a desired and/or alternatively predetermined depth. The conductive wire 140 may form conductive wiring and may be provided to fill the inside of the trench 120a. The trench 120a may have a first width W1 and a region R of the first dielectric layer 120 surrounding the trench 120a may have a second width W2. The second width W2 may be greater than the first width W1. The first dielectric layer 120, in the region R, may include a first surface S1, second surface S2, third surface S3, fourth surface S4, and fifth surface S5 defining the trench 120a. The first surface S1 and the fifth surface S5 may be an upper surface of the first dielectric layer 120. The second surface S2, third surface S3, and fourth surface S4 may define a first sidewall, bottom surface, and second sidewall of the trench 120a, but example embodiments are not limited thereto.

The conductive wire 140 may be formed of metal or a metallic material. The conductive wire 140 may include at least one of a metal, a metal alloy, or a combination thereof. Herein, the metal applied to the conductive wire 140 may include at least one of, for example, copper (Cu), ruthenium (Ru), Al, cobalt (Co), tungsten (W), molybdenum (Mo), titanium (Ti), tantalum (Ta), nickel (Ni), platinum (Pt), chromium (Cr), rhodium (Rh), iridium (Ir), palladium (Pd), or osmium (Os). However, the present disclosure is not limited thereto, and other various metals may be used in the conductive wire 140.

Meanwhile, the size of semiconductor devices has gradually decreased for high integration of the semiconductor devices, and thus the line width of a conductive wire is also decreasing. However, the decrease in the line width of the conductive wire may lead to an increase in the density of a current in the conductive wire, increasing an electrical resistance of the conductive wire. The increase in the electrical resistance causes an electromigration phenomenon, resulting in a defect in the conductive wire and thus a damage to the conductive wire. Herein, electromigration refers to the movement of a substance by the continuous movement of ions in a conductor caused by the transfer of the amount of movement between conductive electrons and atomic nucleuses in the metal.

For the interconnect structure 100 according to an embodiment, the cap layer 150 may be provided on a top surface of the conductive wire 140 to cover the conductive wire 140 made of a metallic material. The cap layer 150 may be provided to cover an exposed top surface of the conductive wire 140 formed in the trench 120a.

The cap layer 150 may be provided to reduce an electrical resistance of the conductive wire 140. The cap layer 150 may be provided to form a uniform thin film in subsequent material deposition. To this end, the cap layer 150 may include doped graphene. The cap layer 150 may include, for example, graphene doped with a group V element. The dielectric layer 160 may be deposited on a top surface of the cap layer 150.

The doped graphene forming the cap layer 150 may include intrinsic graphene or nanocrystalline graphene. The intrinsic graphene may include crystals greater than about 100 nm as crystalline graphene. The nanocrystalline graphene may include crystals having a size of about 0.5 nm to about 150 nm and/or about 0.5 nm to about 100 nm.

The cap layer 150 may be formed to have a thickness of about 3 nm or less. For example, when the doped graphene forming the cap layer 150 includes nanocrystalline graphene, the nanocrystalline graphene may be formed to have a thickness of about 3 nm or less. The doped graphene forming the cap layer 150 may be provided to have a bonding structure in which, for example, a ratio of carbon having sp² bonding to total carbon is about 50% to about 99%.

In the intrinsic graphene, a ratio of carbon having a sp² bonding structure to total carbon measured by X-ray photoelectron spectroscopy (XPS) analysis may be almost 100%. The intrinsic graphene may hardly include hydrogen. The density of the intrinsic graphene may be, for example, about 2.1 g/cc. A ratio of carbon having the sp² bonding structure to total carbon in the nanocrystalline graphene may be, for example, about 50% to about 99%. The nanocrystalline graphene may include, for example, hydrogen of about 1 to about 20 atomic percent (at %). The density of the nanocrystalline graphene may be, for example, about 1.6 to 2.1 g/cc.

A material doped in graphene to form the cap layer 150 may include, as a group V element, at least one of, for example, N, P, As, or Sb. For example, a doped material of the doped graphene forming the cap layer 150 may be at least one of N, P, As, or Sb. The doped graphene forming the cap layer 150 may be formed to have a doping concentration of about 0.1% to about 30%, and may be provided to have a surface energy with a water contact angle of about 75 degrees or less.

The doped graphene forming the cap layer 150 may be directly grown on the top surface of the conductive wire 140. For example, when the graphene is grown, a doping gas including a doping element, e.g., an N-component, may be injected to form graphene doped with a dopant. As another example, after the graphene is grown, the graphene may be doped by plasma-treating the graphene with a gas containing, for example, a doping element, e.g., an N-component. When the graphene is post-treated with gas plasma after the graphene is grown, the dopant may be mainly doped on a surface of the graphene.

When the doped graphene as the cap layer 150 is formed on the top surface of the conductive wire 140, the surface energy of the doped graphene may increase in comparison to the undoped graphene. As such, by forming the cap layer 150 including the doped graphene, the resistance of the conductive wire 140 may be reduced and adhesion may be improved. In addition, when the dielectric layer 160 is deposited on the cap layer 150 through a subsequent process, a uniform thin film may be formed by increasing the surface energy of the doped graphene. That is, by including the cap layer 150 including doped graphene on the top surface of the conductive wire 140, the resistance characteristics and adhesion of the interconnect structure 100 may be improved, and a uniform thin film may be formed in the deposition of the dielectric layer 160 on the cap layer 150 through the subsequent process. The dielectric layer 160 may include a first portion P1 on the first surface S1 of the first dielectric layer 120, a second portion P2 over the trench 120a, and a third portion P3 on the fifth surface S5 of the first dielectric layer 120, but example embodiments are not limited thereto.

In the current embodiment, the doped graphene forming the cap layer 150 may be formed to a thickness of approximately 3 nm or less. However, the present disclosure is not limited thereto, and the doped graphene forming the cap layer 150 may be formed to a different thickness.

For the interconnect structure 100 according to an embodiment, the cap layer 150 may be formed on the top surface of the conductive wire 140 with the doped graphene, thereby reducing the electrical resistance of the conductive wire 140 and limiting and/or preventing a damage to the conductive wire 140 due to electromigration. In addition, the surface energy of the graphene is increased by forming the cap layer 150 with the doped graphene, thereby improving adhesion with a subsequent deposition material layer formed on the cap layer 150, for example, the dielectric layer 160 and thus enabling uniform thin film deposition.

As described above, the interconnect structure 100 may be applied to a BEOL structure of, for example, DRAM, logic element, etc., to configure an electronic device. For example, in order to apply the interconnect structure 100 to the BEOL structure, a conductive wire electrically connected to the conductive wire 140 may be additionally formed, or an interlayer dielectric (ILD) layer may be formed on the dielectric layer 120. For this subsequent process, the dielectric layer 160 may be formed over the top surface of the cap layer 150 and the dielectric layer 120 as shown in FIG. 2, and then a patterning process, a deposition process, etc., may be performed.

The dielectric layer 160 may be, for example, an etch stop layer. For example, the dielectric layer 160 may be formed by depositing a silicon carbon nitride (SiCN) thin film. In FIG. 2, it is shown that the dielectric layer 160 is deposited to cover the entire top surface of the cap layer 150 and the dielectric layer 120, and the dielectric layer 160 may be patterned to form the BEOL structure. For example, the dielectric layer 160 may be patterned such that a partial region including the top surface of the cap layer 150 is exposed. In addition, an interlayer dielectric layer, etc., may be deposited, or a conductive wire, etc., may be additionally formed.

At this time, the cap layer 150 including the doped graphene may have an increased surface energy in comparison to the undoped graphene and thus may have improved adhesion, such that a uniform thin film may be formed when the dielectric layer 160 is deposited.

Meanwhile, a barrier layer 130 may be formed on an inner wall of the trench 120a. Herein, the barrier layer 130 may be provided to cover a side surface and a bottom surface of the conductive wire 140 between the dielectric layer 120 and the conductive wire 140. The barrier layer 130 may limit and/or prevent a material forming the conductive wire 140 from being diffused. Meanwhile, the barrier layer 130 may further serve as an adhesive layer between the dielectric layer 120 and the conductive wire 140.

The barrier layer 130 may include a single-layer structure or a multilayer structure in which a plurality of layers of different materials are stacked. The barrier layer 130 may include, for example, a metal, a metal alloy, a metal nitride, etc. As an example, the barrier layer 130 may include Ta, Ti, Ru, ruthenium tantalum (RuTa), iridium tantalum (IrTa), W, tantalum nitride (TaN), titanium nitride (TiN), ruthenium nitride (RuN), iridium tantalum nitride (IrTaN), titanium silicon nitride (TiSiN), Co, manganese (Mn), manganese oxide (MnO), or tungsten nitride (WN). However, this is merely an example, and other various materials may be used as the barrier layer 130. For example, the barrier layer 130 may include graphene (intrinsic graphene or nanocrystalline graphene) as in other embodiments described below. A liner layer (not shown) may be further provided between the conductive wire 140 and the barrier layer 130 to improve adhesion between the conductive wire 140 and the barrier layer 130.

For the interconnect structure 100 according to the current embodiment, the cap layer 150 including the doped graphene may be formed to cover the conductive wire 140, thereby reducing the resistance of the conductive wire 140, improving adhesion, and forming the dielectric layer 160 to a uniform thickness in subsequent material deposition, e.g., deposition of the dielectric layer 160.

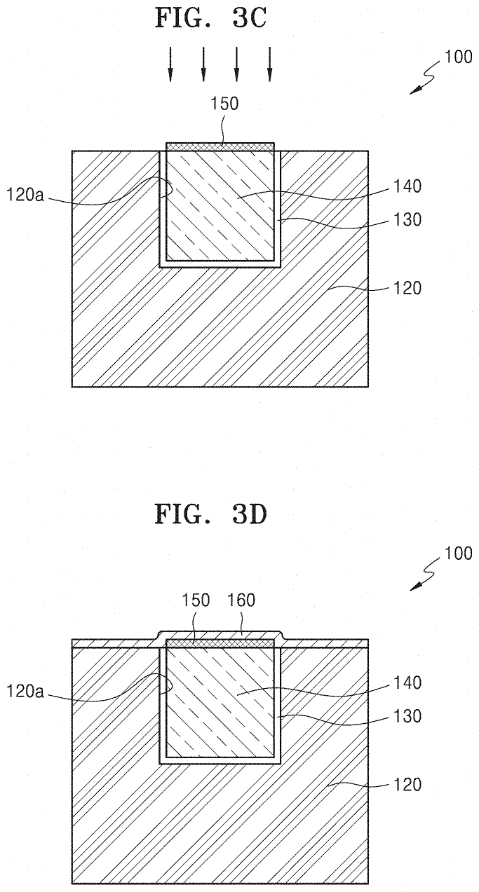

FIGS. 3A to 3D are cross-sectional views schematically illustrating a method of manufacturing the interconnect structure 100 according to an embodiment.

Referring to FIG. 3A, the dielectric layer 120 may be formed on a substrate. The dielectric layer 120 may be formed on the substrate through a deposition process used in a general semiconductor manufacturing process, e.g., chemical vapor deposition (CVD), plasma enhanced CVD (PECVD), spin coating, etc.

The dielectric layer 120 may include, for example, a low-k dielectric material. For example, the dielectric layer 120 may include a dielectric material having a dielectric constant of about 3.6 or less. The dielectric layer 120 may have a single-layer structure or a multi-layer structure in which different materials are stacked. The dielectric layer 120 may be an IMD layer. For example, the dielectric layer 120 may include SiOCH, etc. However, this is merely an example, and the present disclosure is not limited thereto.

Next, the trench 120a may be formed to a desired and/or alternatively predetermined depth in the dielectric layer 120. The trench 120a may be formed, for example, through a photolithography process and an etching process.

Next, the barrier layer 130 may be formed on an inner wall of the trench 120a. Here, the barrier layer 130 may be formed through a deposition process used in a general semiconductor manufacturing process. The barrier layer 130 may include, for example, a metal, a metal alloy, a metal nitride, graphene, etc. However, the present disclosure is not limited thereto. The barrier layer 130 may include a single-layer structure or a multilayer structure in which a plurality of layers are stacked.

Referring to FIG. 3B, the conductive wire 140 may be formed on the barrier layer 130. Herein, the conductive wire 140 may be formed to be fill the inside of the trench 120a. The conductive wire 140 may be formed by, for example, CVD, PECVD, physical vapor deposition (PVD), electroplating, chemical solution deposition, electroless plating, etc. When the conductive wire 140 is formed through electroplating, a plating seed layer (not shown) for promoting electroplating may be formed on the surface of the barrier layer 130 before the conductive wire 140 is formed. Such a plating seed layer may include Cu, Cu alloy, Ir, Ir alloy, Ru, or Ru alloy, etc., which may be merely an example.

The conductive wire 140 may include at least one of a metal, a metal alloy, or a combination thereof. Herein, the metal may include at least one of Cu, Ru, Al, Co, W, Mo, Ti, Ta, Ni, Pt, Cr, Rh, Ir, Pd, or Os. However, the present disclosure is not limited thereto. Herein, the top surface of the dielectric layer 120, the top surface of the barrier layer 130, and the top surface of the conductive wire 140 may be processed through a planarization process. Here, the planarization process may include, for example, a chemical mechanical polishing (CMP) process, a grinding process, etc., but is not limited thereto.

Referring to FIG. 3C, the doped graphene forming the cap layer 150 may be deposited on the top surface of the conductive wire 140. The graphene of the cap layer 150 may include intrinsic graphene or nanocrystalline graphene, and may be doped through doping gas injection during the growth of the graphene or doped by a doping gas plasma treatment after the growth of the graphene. As described above, the intrinsic graphene may include crystals greater than about 100 nm, and the nanocrystalline graphene may include crystals having a size of about 0.5 nm to about 150 nm. A material doped in the graphene to form the cap layer 150 may include, a group V element, for example, at least one of N, P, As, or Sb. The doped graphene forming the cap layer 150 may be directly grown on the top surface of the conductive wire 140. For example, when the graphene is grown, a doping gas including a doping element, e.g., an N-component, may be injected to form graphene doped with a dopant. As another example, after the graphene is grown, the graphene may be doped by plasma-treating the graphene with a gas containing, for example, a doping element, e.g., an N-component. Here, the dopant may be mainly doped on the surface of the graphene. The cap layer 150, that is, the doped graphene, may be formed to a thickness of approximately 3 nm or less, but is not limited thereto.

Referring to FIG. 3D, the dielectric layer 160 may be deposited over the cap layer 150 and the dielectric layer 120 for a subsequent process for applying the interconnect structure 100 to the BEOL structure.

The dielectric layer 160 may be formed on the substrate through a deposition process used in a general semiconductor manufacturing process, e.g., CVD, PECVD, spin coating, etc. The dielectric layer 160 may be, for example, an etch stop layer. For example, the dielectric layer 160 may be formed by depositing a silicon carbon nitride (SiCN) thin film.

The cap layer 150 includes the doped graphene and thus may have an increased surface energy in comparison to the undoped graphene, such that a uniform thin film may be formed during the deposition of the dielectric layer 160.

In FIG. 3D, it is shown that the dielectric layer 160 is deposited to cover the entire top surface of the cap layer 150 and the dielectric layer 120, and the dielectric layer 160 may be patterned to form a subsequent BEOL structure. For example, the dielectric layer 160 may be patterned such that a partial region including the top surface of the cap layer 150 is exposed. In addition, an interlayer dielectric layer, etc., may be deposited on the dielectric layer 160, or a conductive wire, etc., may be additionally formed.

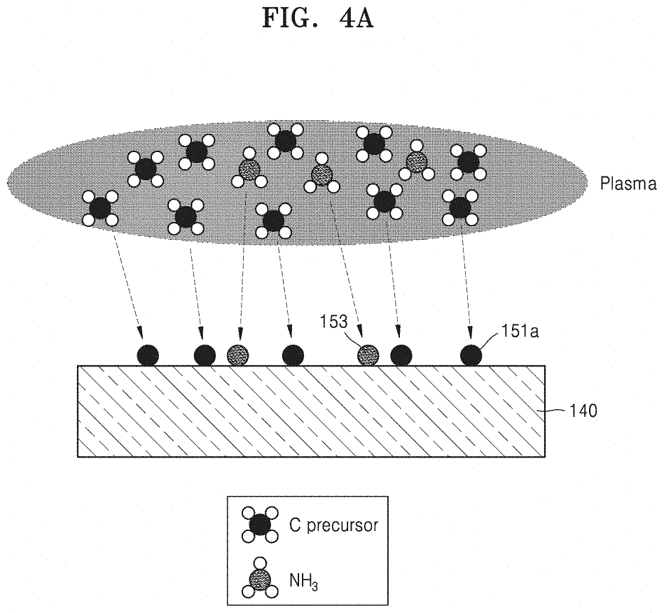

FIGS. 4A and 4B show an example of a process of forming the cap layer 150 including the doped graphene. FIGS. 4A and 4B show an example where doping gas is injected together during direct graphene growth.

Referring to FIGS. 4A and 4B, graphene 151 may be directly grown on the top surface of the conductive wire 140 by the PECVD process, and the cap layer 150 with the surface energy adjusted by doping of a dopant 153 may be formed.

Formation of the doped graphene may be performed in a reaction chamber (not shown). For example, the surface of the conductive wire 140 may be pre-treated before the growth of the graphene. A pre-treatment gas injected for plasma generation in the reaction chamber in a pre-treatment process of the conductive wire 140 may include, for example, at least one of inert gas, hydrogen, oxygen, ammonia, chlorine, bromine, fluorine, or fluorocarbon. The inert gas may include, for example, at least one of an argon gas, a neon gas, a nitrogen gas, a helium gas, a krypton gas, or a xenon gas. Here, the pre-treatment process of the conductive wire 140 may be omitted. By applying plasma power to a state where a bias is applied to a portion on which the graphene is to be directly grown, e.g., the conductive wire 140, charges formed on the surface of the conductive wire 40 may serve to induce adsorption of activated carbon in the graphene growth process. Moreover, when gas plasma is generated by applying the plasma power to the state where the bias is applied to the conductive wire 140, an activated site capable of inducing the adsorption of activated carbon may be formed on the surface of the conductive wire 140.

In order to directly grow the graphene on the top surface of the conductive wire 140 in the reaction chamber, a PECVD process may be performed as shown in FIGS. 4A and 4B.

To directly grow the graphene on the top surface of the conductive wire 140, a reaction gas for growing the graphene may be injected into the reaction chamber. In addition to the reaction gas, the doping gas may be injected into the reaction chamber.

The reaction gas may include a carbon source. Herein, the carbon source may be a source for supplying carbon for the growth of the graphene. The carbon source may include, for example, at least one of a hydrocarbon gas or a vapor of a liquid precursor including carbon. Here, the hydrocarbon gas may include, for example, a methane gas, an ethylene gas, an acetylene gas, or a propylene gas. The liquid precursor including carbon may include, for example, benzene, toluene, xylene or anisole, hexane, octane, isopropyl alcohol, ethanol, etc. However, the above-mentioned carbon source material is merely an example, and other various materials may be used as a carbon source material.

The reaction gas may further include at least one of an inert gas or a hydrogen gas. The inert gas may include at least one of an argon gas, a neon gas, a nitrogen gas, a helium gas, a krypton gas, or a xenon gas.

For example, for the direct growth of graphene, a mixed gas of a carbon source gas, an inert gas, and a hydrogen gas may be used as the reaction gas. A mixing ratio of the reaction gas injected into the reaction chamber may be changed variously according to graphene growth conditions.

Meanwhile, the doping gas may include at least one of NH₃, BH₃, B₂H₆, AsH₃, PH₃, TMSb, TMIn, or TMGa.

On the other hand, for the direct growth of the graphene using a PECVD process, power for plasma generation in the reaction chamber may be applied from a plasma power source (not shown). The plasma power applied in the graphene growth process may be less than plasma power applied in the pre-treatment process. For example, the plasma power applied in the graphene growth process may be less than 600 W, and may be specifically less than or equal to 300 W. Here, the plasma power applied in the graphene growth process is not limited thereto, and various powers may be applied.

As the plasma power source, for example, a radio frequency (RF) plasma generator or an MW plasma generator may be used. The RF plasma generator may generate RF plasma having a frequency range of, for example, about 3 MHz to about 100 MHz, and the MW plasma generator may generate MW plasma having a frequency range of, for example, about 0.7 GHz to about 2.5 GHz. However, such a frequency range is merely an example, and other frequency ranges may be used. Meanwhile, as the plasma power source, a plurality of RF plasma generators or a plurality of MW plasma generators may be used.

Upon application of power for plasma generation to the inside of the reaction chamber from the plasma power source, plasma of the reaction gas may be generated inside the reaction chamber. In addition, the plasma of the doping gas may be generated inside the reaction chamber.

Upon application of the power for plasma generation to the inside of the reaction chamber from the plasma power source, the plasma of a carbon (C) precursor and a dopant precursor may be generated in the reaction chamber as shown in FIG. 4A. FIG. 4B shows an example of a case where direct-grown graphene 151 doped with the dopant 153 is directly grown on the surface of the conductive wire 140 by the plasma including the C precursor and the dopant precursor (NH₃) for graphene growth. In FIG. 4A, reference numeral 151a indicates an activated carbon component that forms the direct-grown graphene. In addition, as shown in FIG. 4A as an example, when the doping gas includes NH₃, the dopant 153 may correspond to an N component.

In the direct growth process of the graphene 151, a process temperature and a process pressure inside the reaction chamber may be variously changed according to the graphene growth conditions. For example, the growth process of the graphene 151 may be performed at a relatively low temperature similarly to the pre-treatment process of the conductive wire 140. For example, the growth process of the graphene 151 may be performed at a process temperature of about 1000 degrees or less. As a detailed example, the direct growth process of the graphene 151 may be performed at a process temperature of about 700 degrees or less (e.g., about 300 degrees to about 600 degrees).

The process pressure at which the growth process of the graphene 121 is performed may be higher than, for example, a process pressure at which the pre-treatment process of the conductive wire 140 is performed. However, the present disclosure is not limited thereto, and the process pressure at which the growth process of the graphene 151 is performed may be changed variously according to the graphene growth conditions.

Upon application of plasma power to the inside of the reaction chamber, the C precursor and the dopant precursor (e.g., NH₃) may be activated by the plasma of the reaction gas, and the activated carbon 151a and the dopant 153 may move toward the surface of the conductive wire 140, such that the dopant 153 may be doped into the grown graphene 151 and thus the doped graphene with a controlled surface energy, e.g., the cap layer 150 may be formed, as shown in FIG. 4B.

In this case, when the cap layer 150 having the doped graphene with the adjusted surface energy is formed by injection of the dopant 153 into the grown graphene 151, the dopant 153 may be doped in a range of about 0.1% to about 30%, (e.g., about 0.1% to about 5%), where the range may be an at % (e.g., 0.1 at % to about 30 at %). In addition, the graphene 151 may be formed of nanocrystalline graphene including crystals having a domain size of about 0.5 to about 150 nm.

As such, by injecting a reaction gas and a doping gas for the growth of the graphene into the reaction chamber and performing a PECVD process, thereby forming the cap layer 150 adjusted to increase the surface energy of the graphene 151 by doping with the dopant 153, the resistance characteristics of the conductive wire 140 may be improved, and thus the problem of increasing resistance due to a decrease in the width of the metal wire may be solved. Moreover, by forming the cap layer 150 with doped graphene, adhesion may be improved compared to the application of the undoped graphene. For example, when the conductive wire 140 includes Cu and the graphene 151 of the cap layer 150 is doped with an N component, bonding of Cu—N is stronger than that of Cu—C and thus adhesion may be improved.

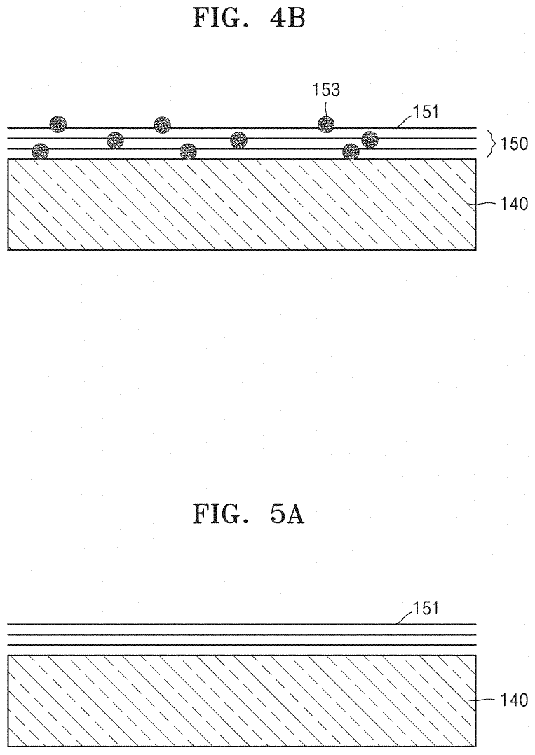

While an example where the graphene 151 is doped with the dopant 153 by the injection of the doping gas in the growth of the graphene has been described with reference to FIGS. 4A and 4B, doping may be performed by a subsequent process after the growth of the graphene as shown in FIGS. 5A through 5C.

FIGS. 5A to 5C show another example of a process of forming the cap layer 150 including doped graphene.

Referring to FIG. 5A, as described above, the conductive wire 140 may be pre-treated before the growth of the graphene. In the reaction chamber, the PECVD process may be performed to directly grow the graphene 151 on the top surface of the conductive wire 140.

To directly grow the graphene 151 on the top surface of the conductive wire 140, the reaction gas for the growth of the graphene may be injected into the reaction chamber. In this case, the reaction gas may include a carbon source as described above. The reaction gas may further include at least one of an inert gas or a hydrogen gas as described above.

For example, for the growth of the graphene 151, a mixed gas of a carbon source gas, an inert gas, and a hydrogen gas may be used as the reaction gas. A mixing ratio of the reaction gas injected into the reaction chamber may be changed variously according to the graphene growth conditions.

To directly grow the graphene 151 on the top surface of the conductive wire 140 using the PECVD process, power for plasma generation may be applied to the inside of the reaction chamber from the plasma power source (not shown). As described above, the plasma power applied in the growth process of the graphene 151 may be less than, for example, the plasma power applied in the pre-treatment process of the conductive wire 140.

Upon application of power for plasma generation to the inside of the reaction chamber from the plasma power source, plasma of the reaction gas may be generated inside the reaction chamber. When power for plasma generation is applied to the inside of the reaction chamber from the plasma power source, the plasma of the C precursor may be generated in the reaction chamber, and the graphene 151 may be grown on the surface of the conductive wire 140 by the plasma of the C precursor as shown in FIG. 5A. In the growth process of the graphene 151, a process temperature and a process pressure inside the reaction chamber may be variously changed according to the graphene growth conditions. For example, as described above, the growth process of the graphene 151 may be performed at a relatively low temperature similarly to the pre-treatment process of the conductive wire 140. The process pressure at which the growth process of the graphene 151 is performed may be higher than, for example, a process pressure at which the pre-treatment process of the conductive wire 140 is performed, as described above. However, the present disclosure is not limited thereto, and the process pressure at which the growth process of the graphene 151 is performed may be changed variously according to the graphene growth conditions.

Referring to FIG. 5B, in a state where the graphene 151 is grown to be formed to a desired and/or alternatively predetermined thickness, the doping gas for doping the graphene 151 may be injected into the reaction chamber. The doping gas may include at least one of NH₃, BH₃, B₂H₆, AsH₃, PH₃, TMSb, TMIn, or TMGa.

In this case, by applying the plasma power to the inside of the reaction chamber, the doping gas may be activated to a plasma state and the graphene 151 may be doped with a dopant 153′. In this case, the dopant 153′ may be mainly doped on the surface of the graphene 151. As such, by doping the graphene 151 through a subsequent process, the cap layer 150 changed to have an increased surface energy may be formed.

As such, the graphene 151 may also be doped by being plasma-treated through injection of the doping gas to the reaction chamber after the growth of the graphene 151, thus improving adhesion between the cap layer 150 and the conductive wire 140 and enhancing the resistance characteristics of the conductive wire 140, thereby to solve the resistance increase problem caused by the decrease in the width of the metal wire.

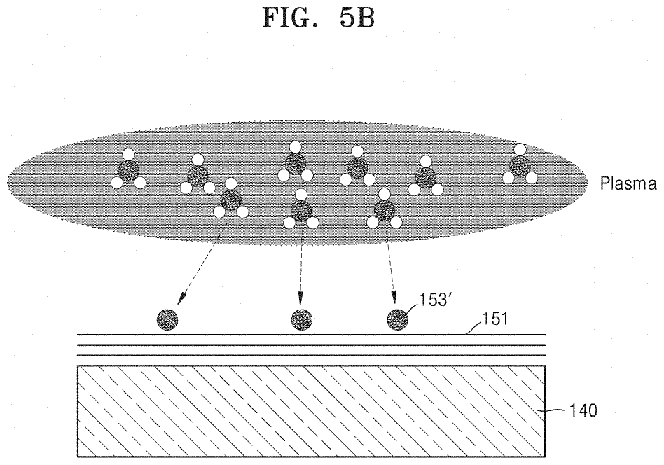

FIG. 6 shows a comparison of analysis results of undoped graphene and graphene doped by injection of an NH₃ gas during growth. As shown in FIG. 6, it may be seen that when the NH₃ gas is injected during the growth of the graphene, there is bonding of C—N.

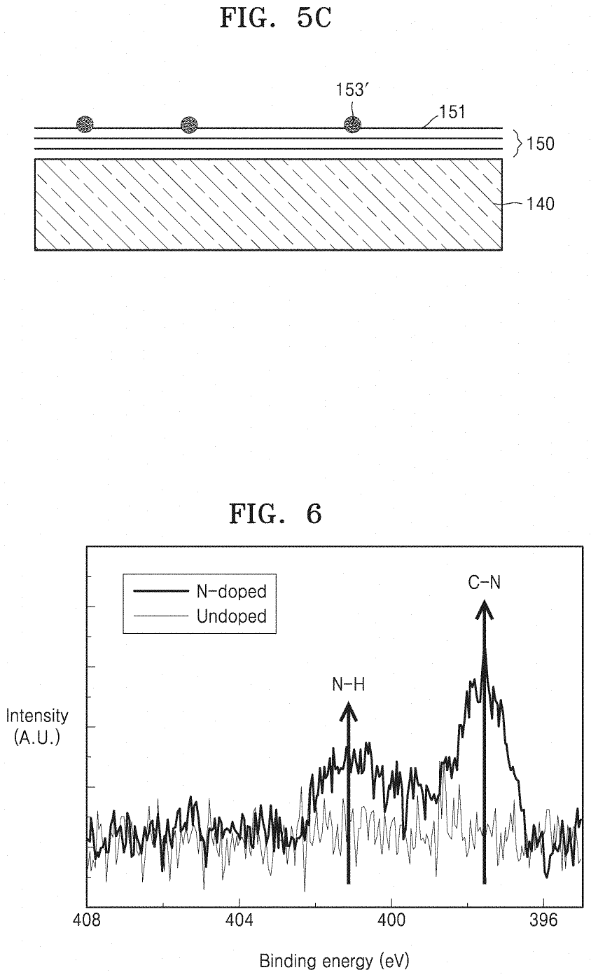

FIG. 7A shows a water contact angle with respect to undoped graphene, FIG. 7B shows a water contact angle change of graphene doped by injection of an NH₃ gas during the growth of the graphene, and FIG. 7C shows a water contact angle change of graphene doped by NH₃ plasma treatment after the growth of the graphene.

As may be seen from comparison among FIGS. 7A, 7B, and 7C, the undoped graphene has a water contact angle of about 88.1 degrees, whereas the graphene that is N-doped by injection of the NH₃ gas during the growth of the graphene has a water contact angle of 72.3 degrees, and the graphene doped by NH₃ plasma treatment after the growth of the graphene has a water contact angle of 36.0 degrees, such that a surface energy of the doped graphene has changed. A decrease in the water contact angle may correspond to an increase in the surface energy. Thus, when the doped graphene is formed by injection of the doping gas during the growth of the graphene or treatment with doping gas plasma after the growth of the graphene, the surface energy of the graphene may be adjusted to increase and the doped graphene having a surface energy showing a water contact angle of 75 degrees or less may be formed.

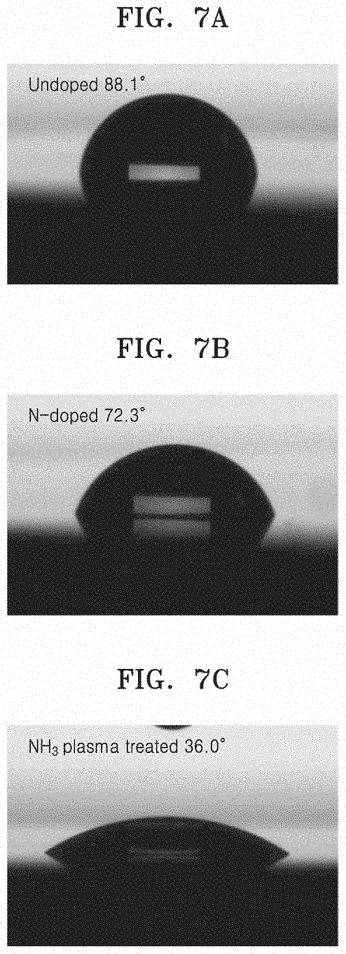

FIG. 8 shows a water contact angle change of graphene when the graphene is plasma-treated with an NH₃ gas after the growth of the graphene.

As may be seen from FIG. 8, in plasma treatment, the water contact angle of the graphene decreases as the plasma power increases, and the water contact angle of the graphene may further decrease when a plasma treatment time increases. Herein, the decrease in the water contact angle may correspond to the increase in the surface energy. Thus, when the doped graphene is formed by injection of the doping gas during the growth of the graphene or the doped graphene is formed with a dopant mainly distributed on the surface thereof by treatment with doping gas plasma after the growth of the graphene, the surface energy of the graphene may be adjusted to increase.

Thus, according to the interconnect structure 100 including the cap layer 150 including the doped graphene, the electrical resistance of the conductive wire may be lowered, and a uniform thin film may be formed in deposition of the dielectric layer 160 such as a subsequent deposition material like SiCN, etc., due to the increase in the surface energy of the doped graphene.

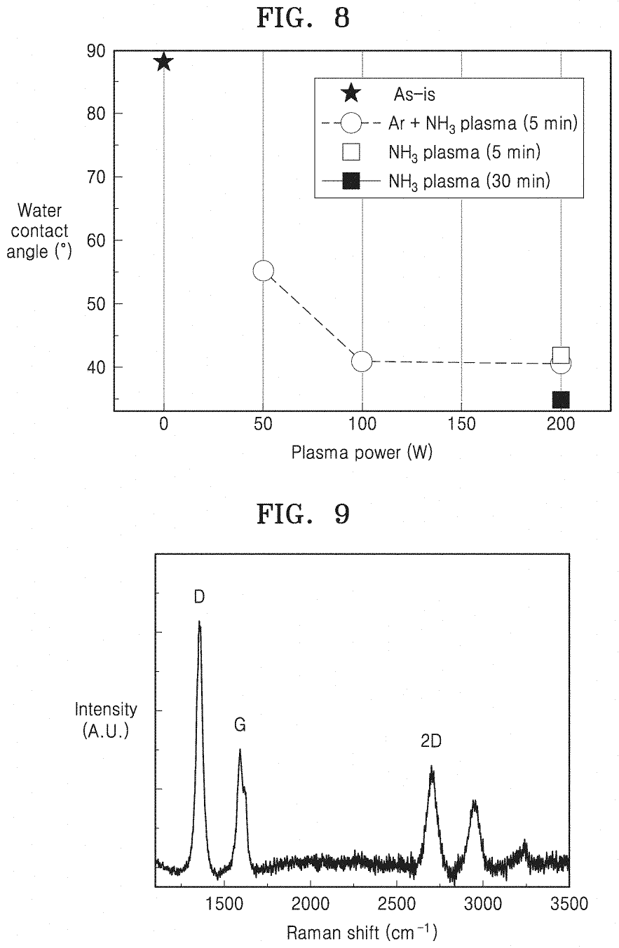

FIG. 9 shows a Raman spectrum indicating nanocrystalline graphene.

Referring to FIG. 9, a peak D may be a peak near 1350 cm⁻¹, associated with a defect. A full width at half maximum (FWHM) of the peak D is associated with a crystalline size of the graphene, such that the FWHM of the peak D may decrease as a domain size increases. A peak 2D may be a peak near 2700 cm⁻¹, associated with a graphene film quality. As crystallinity is improved, the peak 2D may be stronger.

In the interconnect structure 100 according to an embodiment, the cap layer 150 may include doped graphene, and the graphene may be formed of, for example, nanocrystalline graphene. For example, the graphene of the cap layer 150 may be formed such that a ratio of an intensity of the peak D with respect to an intensity of a peak G is, for example, about 3 or less, a ratio of an intensity of the peak 2D with respect to an intensity of a peak G is, for example, about 0.1 or more, and an FWHM of the peak D is, for example, about 60 cm⁻¹ or less, for example, about 25 to about 60 cm⁻¹.

In the interconnect structure 100 according to an embodiment, the cap layer 150 may include doped graphene, and the graphene may be formed of, for example, nanocrystalline graphene. The graphene of the cap layer 150 may include crystals having a size of, for example, about 0.5 nm to about 150 nm, and a ratio of carbon having a sp² bonding structure with respect to total carbon may be, for example, about 50% to about 99%. Herein, the nanocrystalline graphene may include, for example, hydrogen of about 1 to about 20 at %. In addition, the density of the nanocrystalline graphene may be, for example, about 1.6 to about 2.1 g/cc, and the surface resistance of the nanocrystalline graphene may be, for example, greater than about 1000 Ohm/sq.

As such, the interconnect structure 100 according to an embodiment may form the cap layer 150 formed in the conductive wire 140 with the doped graphene, thus reducing the resistance of the conductive wire 140 and improving adhesion to a subsequent deposition material layer formed on the cap layer 150, e.g., the dielectric layer 160, thereby allowing uniform thin film deposition.

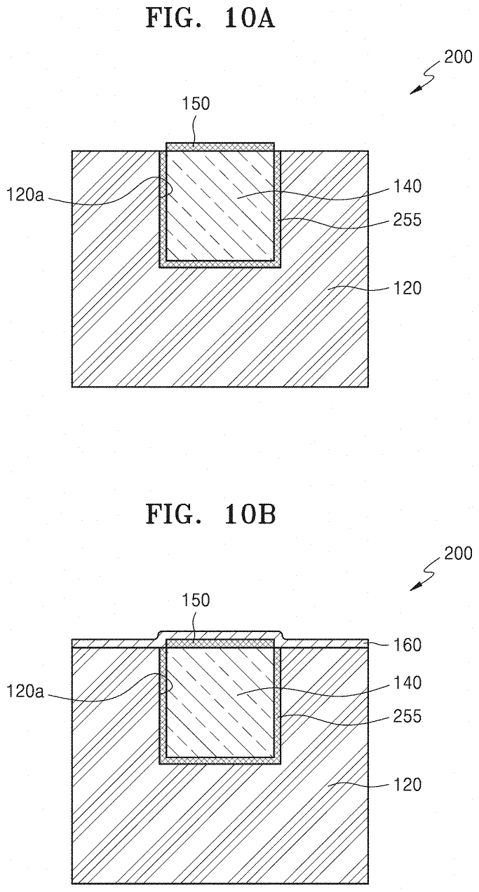

FIG. 10A is a cross-sectional view showing an interconnect structure 200 according to another embodiment.

Referring to FIG. 10A, the interconnect structure 200 may include the dielectric layer 120 where the trench 120a is formed, the conductive wire 140, and the cap layer 150. The interconnect structure 200 may further include a cap layer 255 to cover a side surface and a bottom surface of the conductive wire 140 inside the trench 120a. The dielectric layer 120, the conductive wire 140, and the cap layer 150 have been described above and thus will not be described at this time.

The cap layer 255 may be provided on the side surface and the bottom surface of the conductive wire 140. The cap layer 255 may be provided to cover the side surface and the bottom surface of the conductive wire 140 inside the trench 120a. The cap layer 255 may include doped graphene like the cap layer 150, and may be formed inside the trench 120a. The cap layer 255, like the cap layer 150, may be formed with graphene doped by injection of the doping gas during the growth of the graphene inside the trench 120a or may be formed with graphene doped by post-treatment with doping gas plasma after the deposition of the graphene inside the trench 120a.

In the current embodiment, the cap layer 150 may be provided on the top surface of the conductive wire 140 and the cap layer 255 may be additionally provided on the bottom surface and the side surface of the conductive wire 140, thereby enhancing resistance reduction and reliability improvement. The cap layer 255 may serve as a barrier layer, and in this case, since weak adhesion between a metal material of the conductive wire 140, e.g., Cu, and graphene may be improved by doping of the graphene, a liner layer for improving adhesion between the conductive wire 140 and the barrier layer is unnecessary.

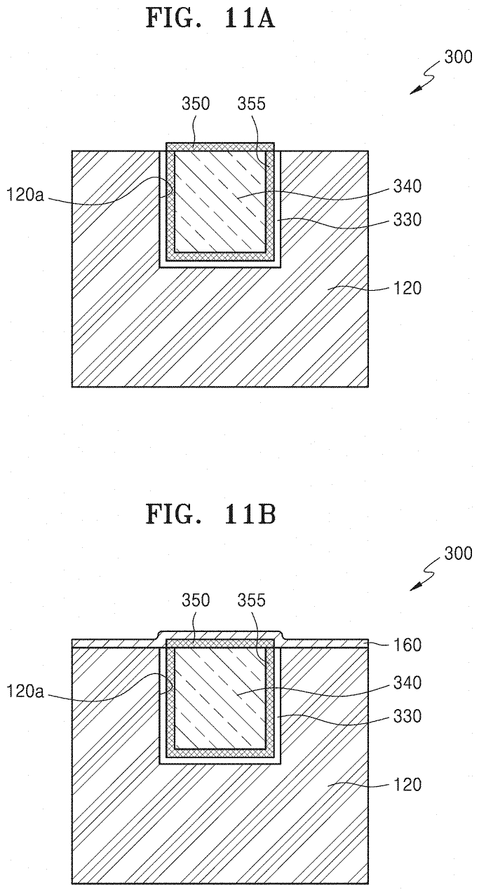

FIG. 11A is a cross-sectional view showing an interconnect structure 300 according to another embodiment.

Referring to FIG. 11A, the interconnect structure 300 may include the dielectric layer 120 where the trench 120a is formed, a conductive wire 340, a barrier layer 330, and a cap layer 350 provided on a top surface of the conductive wire 340. The interconnect structure 300 may further include the cap layer 355 provided to cover the side surface and the bottom surface of the conductive wire 340 between the barrier layer 330 and the conductive wire 340.

The barrier layer 330 may be provided on an inner wall of the trench 120a. The barrier layer 330 may be provided on the side surface and the bottom surface of the conductive wire 340 between the dielectric layer 120 and the conductive wire 340. The barrier layer 330 may include, for example, a metal, a metal alloy, a metal nitride, graphene, etc. As a specific example, the barrier layer 330 may include Ta, Ti, Ru, RuTa, IrTa, W, TaN, TiN, RuN, IrTaN, TiSiN, Co, Mn, MnO, WN, etc. However, this is merely an example, and other various materials may be used as the barrier layer 330.

The cap layer 350 may be provided on the top surface of the conductive wire 340. The cap layer 350 may include doped graphene. The cap layer 350 may correspond to the cap layer 150 described in the foregoing embodiment.

A cap layer 355 may be provided on the bottom surface and the side surface of the conductive wire 340. The cap layer 355 may be provided to cover the side surface and the bottom surface of the conductive wire 340 between the barrier layer 330 and the conductive wire 340. The cap layer 355 may include doped graphene like the cap layer 350.

The conductive wire 340 may fill the inside of the trench 120a that is provided with the barrier layer 330 and the cap layer 355 on the inner wall thereof. The conductive wire 340 may correspond to the conductive wire 140 described above.

In the current embodiment, the cap layer 355 is further provided on the bottom surface and the side surface of the conductive wire 140, thereby enhancing resistance reduction and reliability improvement. The cap layer 355 may serve as a liner layer for improving adhesion between the conductive wire 340 and the barrier layer 330.

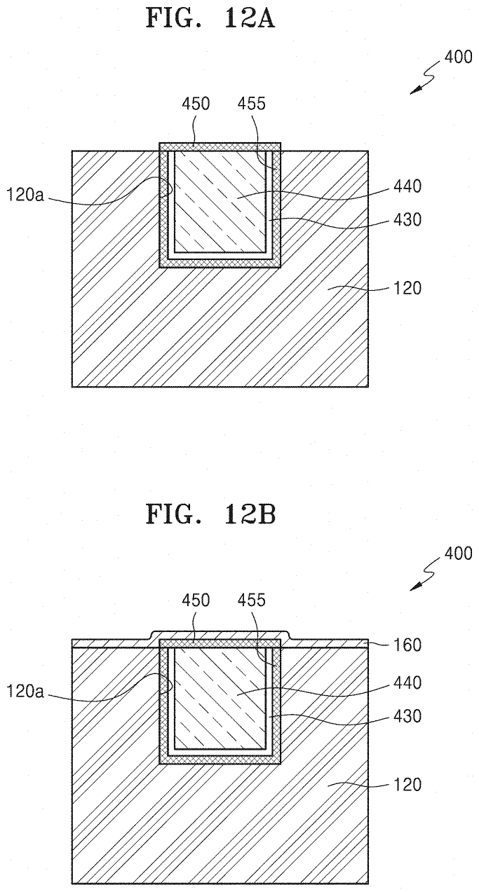

FIG. 12A is a cross-sectional view showing an interconnect structure 400 according to another embodiment.

Referring to FIG. 12A, the interconnect structure 400 may include the dielectric layer 120 where the trench 120a is formed, a conductive wire 440, a barrier layer 430, and a cap layer 450. The interconnect structure 400 may further include a cap layer 455 provided on an inner wall of the trench 120a.

The cap layer 450 may be provided on a top surface of the conductive wire 440 and a top surface of the barrier layer 430. The cap layer 450 may include doped graphene. The cap layer 450 may correspond to the cap layer 150 described in the foregoing embodiment. The cap layer 455 may be provided on the inner wall of the trench 120a. The cap layer 455 may be provided to cover a side surface and a bottom surface of the barrier layer 430 between the dielectric layer 120 and the barrier layer 430. The cap layer 455 may include doped graphene like the cap layer 450.

The barrier layer 430 may be provided on the side surface and the bottom surface of the conductive wire 440 between the cap layer 455 and the conductive wire 440. The barrier layer 430 may include, for example, a metal, a metal alloy, a metal nitride, graphene, etc. As a specific example, the barrier layer 330 may include Ta, Ti, Ru, RuTa, IrTa, W, TaN, TiN, RuN, IrTaN, TiSiN, Co, Mn, MnO, WN, etc. However, this is merely an example, and other various materials may be used as the barrier layer 430.

The conductive wire 440 may fill the inside of the trench 120a that is provided with the cap layer 455 and the barrier layer 330 on the inner wall thereof. The conductive wire 440 may correspond to the conductive wire 140 described above.

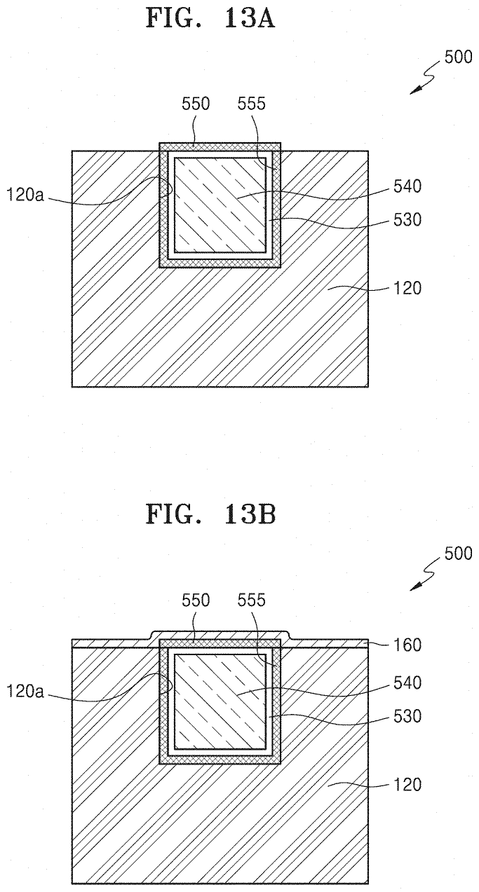

FIG. 13A is a cross-sectional view showing an interconnect structure 500 according to another embodiment.

Referring to FIG. 13A, the interconnect structure 500 may include the dielectric layer 120 where the trench 120a is formed, a conductive wire 540, a barrier layer 530, and a cap layer 550. The interconnect structure 500 may further include a cap layer 555 provided on the inner wall of the trench 120a.

The barrier layer 530 may be provided to cover the top surface, the side surface, and the bottom surface of the conductive wire 540 inside the trench 120a. The barrier layer 530 may include, for example, a metal, a metal alloy, a metal nitride, graphene, etc. As a specific example, the barrier layer 530 may include Ta, Ti, Ru, RuTa, IrTa, W, TaN, TiN, RuN, IrTaN, TiSiN, Co, Mn, MnO, WN, etc. However, this is merely an example, and other various materials may be used as the barrier layer 530.

The cap layer 550 may be provided to cover the top surface of the barrier layer 530. The cap layer 550 may include doped graphene. The cap layer 550 may correspond to the cap layer 150 described in the foregoing embodiment. The cap layer 555 may be provided on the inner wall of the trench 120a. The cap layer 555 may be provided to cover a side surface and a bottom surface of the barrier layer 530 between the dielectric layer 120 and the barrier layer 530. The cap layer 555 may include doped graphene like the cap layer 550.

The conductive wire 540 may fill the inside of the trench 120a that is provided with the cap layer 555 and the barrier layer 530 on the inner wall thereof and to be covered with the barrier layer 530 on the top surface thereof. The conductive wire 540 may correspond to the conductive wire 140 described above.

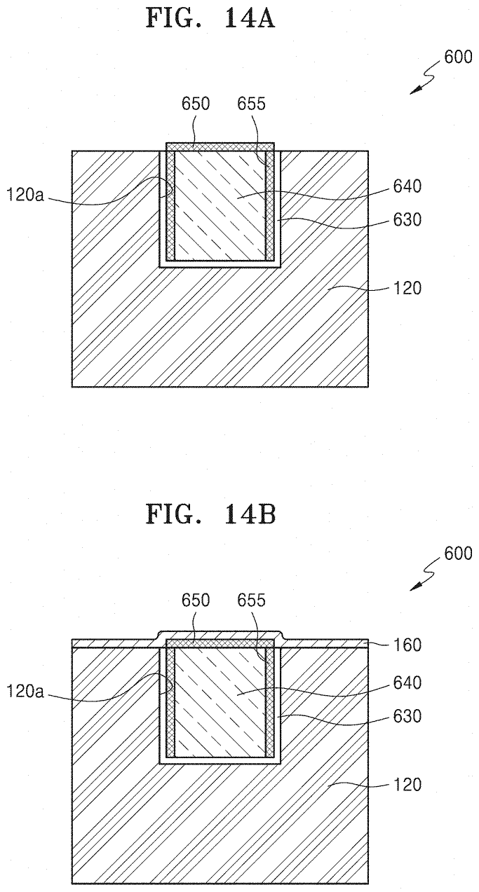

FIG. 14A is a cross-sectional view showing an interconnect structure 600 according to another embodiment.

Referring to FIG. 14A, the interconnect structure 600 may include the dielectric layer 120 where the trench 120a is formed, a conductive wire 640, a barrier layer 630, and a cap layer 650. The interconnect structure 600 may further include a cap layer 655 provided to cover a side surface of the conductive wire 640 between the barrier layer 630 and the conductive wire 640. The barrier layer 630 may be provided on an inner wall of the trench 120a. Herein, the barrier layer 630 may be provided on the side surface and the bottom surface of the conductive wire 640 between the dielectric layer 120 and the conductive wire 640.

The cap layer 650 may be provided to cover the top surface of the conductive wire 640. The cap layer 650 may include doped graphene. The cap layer 650 may correspond to the cap layer 150 described in the foregoing embodiment. A cap layer 655 may be provided on the inner wall of the trench 120a. The cap layer 655 may be provided to cover a side surface of the conductive wire 640 between the barrier layer 630 and the conductive wire 640. The cap layer 655 may include doped graphene like the cap layer 650.

The barrier layer 630 may be provided on the inner wall of the trench 120a. The barrier layer 630 may be provided on the side surface and the bottom surface of the conductive wire 640 between the dielectric layer 120 and the conductive wire 640. The barrier layer 630 may include, for example, a metal, a metal alloy, a metal nitride, graphene, etc. As a specific example, the barrier layer 630 may include Ta, Ti, Ru, RuTa, IrTa, W, TaN, TiN, RuN, IrTaN, TiSiN, Co, Mn, MnO, WN, etc. However, this is merely an example, and other various materials may be used as the barrier layer 630.

The conductive wire 640 may fill the inside of the trench 120a that is provided with the barrier layer 630 and the cap layer 655 on the inner wall thereof. The conductive wire 640 may correspond to the conductive wire 140 described above.

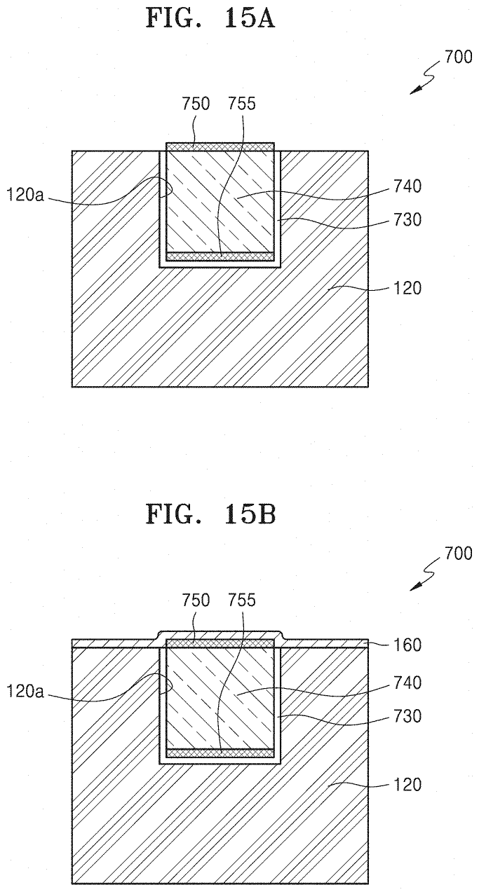

FIG. 15A is a cross-sectional view showing an interconnect structure 700 according to another embodiment.

Referring to FIG. 15A, the interconnect structure 700 may include the dielectric layer 120 where the trench 120a is formed, a conductive wire 740, a barrier layer 730, and a cap layer 750. The interconnect structure 700 may further include a cap layer 755 provided to cover a bottom surface of the conductive wire 740 between the barrier layer 730 and the conductive wire 740.

The barrier layer 730 may be provided on the inner wall of the trench 120a. The barrier layer 730 may be provided on the side surface and the bottom surface of the conductive wire 740 between the dielectric layer 120 and the conductive wire 740. The barrier layer 730 may include, for example, a metal, a metal alloy, a metal nitride, graphene, etc. As a specific example, the barrier layer 730 may include Ta, Ti, Ru, RuTa, IrTa, W, TaN, TiN, RuN, IrTaN, TiSiN, Co, Mn, MnO, WN, etc. However, this is merely an example, and other various materials may be used as the barrier layer 730.

The cap layer 750 may be provided to cover the top surface of the conductive wire 740. The cap layer 750 may include doped graphene. The cap layer 750 may correspond to the cap layer 150 described in the foregoing embodiment.

A cap layer 755 may be provided on a bottom surface of the trench 120a. The cap layer 755 may be provided to cover a bottom surface of the conductive wire 740 between the barrier layer 730 and the conductive wire 740. The cap layer 755 may include doped graphene like the cap layer 750.

The conductive wire 740 may fill the inside of the trench 120a that is provided with the barrier layer 330 on the inner wall thereof. The conductive wire 740 may correspond to the conductive wire 140 described above.

In the interconnect structures 200, 300, 400, 500, 600, and 700 of FIGS. 10A to 15A, the dielectric layer 160 described above may be further deposited on the top surface of the cap layer 150, 350, 450, 550, 670 or 750 and the top surface of the dielectric layer 120 in a subsequent process (see FIGS. 10B, 11B, 12B, 13B, 14B, and 15B). Next, a patterning process and a deposition process may be performed.

In the interconnect structure according to various embodiments described above, by forming the cap layer formed on the top surface of the conductive wire with doped graphene, the resistance of the conductive wire may be reduced and the surface energy of the cap layer may be increased to form the dielectric layer, etc., with a uniform thickness during subsequent material deposition. Such an interconnect structure may be applied, for example, to the BEOL of an electronic device such as a DRAM, a logic element, etc. Although the embodiments have been described above, these are merely examples and various changes may be made therefrom by those of ordinary skill in the art.

For the interconnect structure according to an embodiment, by forming the cap layer formed on the conductive wire with the doped graphene, the resistance of the conductive wire may be reduced and the dielectric layer formed on the cap layer in the subsequent process may be formed as a uniform thin film.

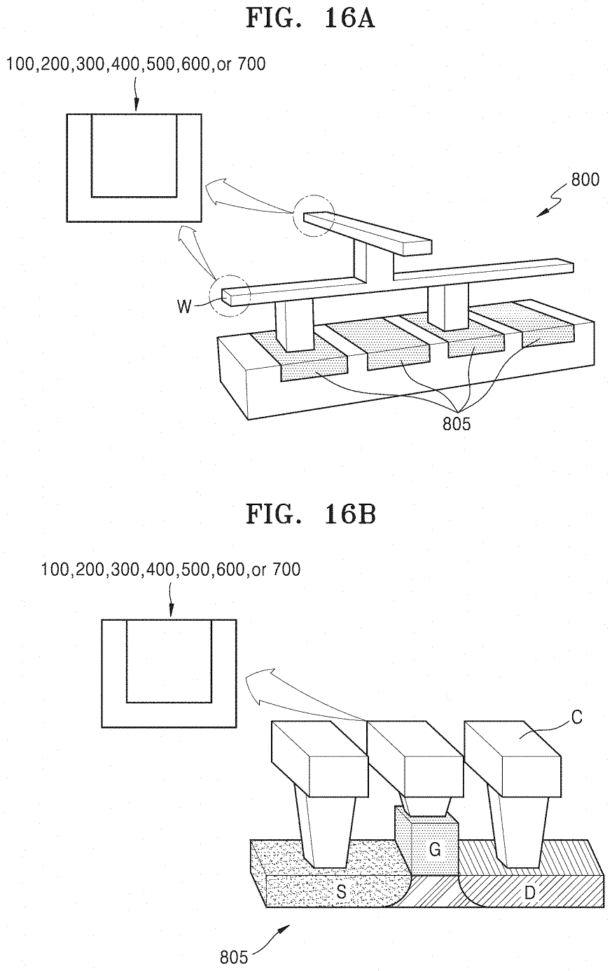

Such an interconnect structure may be applied to the BEOL of an electronic device such as a DRAM, a logic element, etc. For example, FIG. 16A is a conceptual view illustrating a semiconductor device 800 including an interconnect structure according to an example embodiment. FIG. 16B is a conceptual view illustrating an interconnect structure connected to a transistor according to an example embodiment.

Referring to FIG. 16A, according to an example embodiment, the semiconductor device 800 may include a wiring W. The wiring W may include one of the interconnect structures 100, 200, 300, 400, 500, 600, and/or 700 described above in FIGS. 1-2 and 10A to 15B. The wiring W may be connected to a device element 805, such as a DRAM, a transistor, a logic element including a transistor, a resistor, a capacitor, a diode. As shown in FIG. 16B, in one embodiment, the device element 805 may be a transistor including a source S, gate G, and drain D. One of the interconnect structures 100, 200, 300, 400, 500, 600, or 700 may be connected to the gate G. The drain D may be connected to a storage element C, such as a capacitor. In some embodiments, one of the interconnect structures 100, 200, 300, 400, 500, 600, or 700 alternatively (or also) may be connected to the source S and/or drain D.

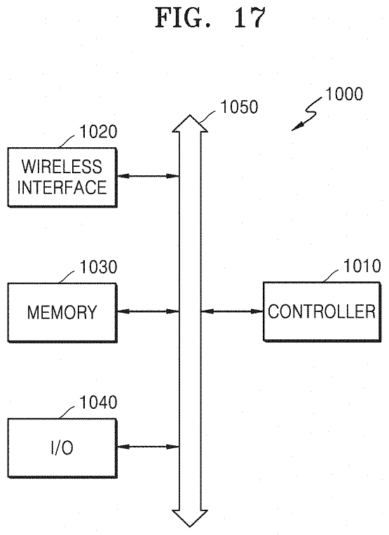

FIG. 17 is a block diagram of an electronic device according to an embodiment.

The electronic device 1000 may form a wireless communication device or a device capable of transmitting and/or receiving information in a wireless environment. The electronic device 1000 may include a controller 1010, an input/output device (I/O) 1020, a memory 1030, and a wireless interface 1040, which are connected to each other through a bus 1050.

The controller 1010 may include at least one selected from the group consisting of a microprocessor, a digital signal processor, and a processing device similar thereto. User's commands may be input through the I/O device 1020 for the controller 1010, and the I/O device 1020 may include at least one selected from the group consisting of a keypad, a keyboard, and a display. The memory 1030 may be used to store instructions executed by controller 1010 and/or store data. For example, the memory 1030 may be used to store user data. The electronic device 1000 may use the wireless interface 1040 to transmit/receive data through a wireless communication network. The wireless interface 1040 may include an antenna and/or a wireless transceiver. In some embodiments, the electronic device 1000 may be used for communication interface protocols (e.g., a third generation communication system such as code division multiple access (CDMA), global system for mobile communications (GSM), north American digital cellular (NADC), extended-time division multiple access (E-TDMA), and/or wide band code division multiple access (WCDMA), a fourth generation communication system such as 4G LTE, a fifth generation communication system and the like). The electronic device 1000 may include at one of the interconnect structures 100, 200, 300, 400, 500, 600, and/or 700 described above in FIGS. 1-2 and 10A to 15B.

One or more of the elements disclosed above may include or be implemented in processing circuitry such as hardware including logic circuits; a hardware/software combination such as a processor executing software; or a combination thereof. For example, the processing circuitry may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. An interconnect structure comprising:
a first dielectric layer including a trench;
a conductive wire filling an inside of the trench;
a first cap layer on a top surface of the conductive wire, the first cap layer including a doped graphene, the doped graphene being graphene doped with a group V element; and
a second dielectric layer on a top surface of first cap layer.

2. The interconnect structure of claim 1, wherein a doping material of the doped graphene comprises at least one of nitrogen (N), phosphorus (P), arsenic (As), or antimony (Sb).

3. The interconnect structure of claim 1, wherein a doping concentration of the doped graphene is about 0.1% to about 30%.

4. The interconnect structure of claim 1, wherein the doped graphene has a surface energy with a water contact angle of 75 degrees or less.

5. The interconnect structure of claim 1, wherein the doped graphene comprises intrinsic graphene or nanocrystalline graphene.

6. The interconnect structure of claim 5, wherein the nanocrystalline graphene comprises crystals having a size of about 0.5 nm to about 150 nm.

7. The interconnect structure of claim 5, wherein the nanocrystalline graphene has a thickness of 3 nm or less.

8. The interconnect structure of claim 5, wherein the doped graphene comprises a bonding structure in which a ratio of carbon having sp² bonding to total carbon is about 50% to about 99%.

9. The interconnect structure of claim 1, wherein the first dielectric layer comprises a dielectric material having a dielectric constant of about 3.6 or less.

10. The interconnect structure of claim 1, wherein the second dielectric layer comprises silicon carbon nitride (SiCN).

11. The interconnect structure of claim 1, further comprising:
a second cap layer in the trench, wherein
the second cap layer comprises the doped graphene.

12. The interconnect structure of claim 1, further comprising:
a barrier layer in the trench.

13. The interconnect structure of claim 12, wherein the barrier layer covers a side surface of the conductive wire and a bottom surface of the conductive wire.

14. An electronic device comprising:
the interconnect structure of claim 1.

15. An interconnect structure comprising:
a first dielectric layer including a trench and a region surrounding the trench of the first dielectric layer, the region of the first dielectric layer defining a sidewall of the trench and including a top surface higher than a bottom of the trench;
a conductive wire in the trench; and
a first cap layer on a top surface of the conductive wire, the first cap layer including a doped graphene, the doped graphene including graphene doped with a group V element, the top surface of the conductive wire being opposite the bottom of the trench.

16. The interconnect structure of claim 15, further comprising:
a second dielectric layer on the first dielectric layer, wherein
the second dielectric layer includes a first portion on the region of the first dielectric layer and a second portion over the trench of the first dielectric layer.

17. The interconnect structure of claim 16, wherein
the first dielectric layer includes silicon oxycarbide (SiOCH), and
the second dielectric layer includes silicon carbide (SiC).

18. The interconnect structure of claim 15, wherein
a doping concentration of the doped graphene is about 0.1% to about 30%, and
the doped graphene includes intrinsic graphene or nanocrystalline graphene.

19. The interconnect structure of claim 15, further comprising:
a second cap layer in the trench between first dielectric layer and the conductive wire, wherein
the second cap layer includes the doped graphene.

20. The interconnect structure of claim 15, wherein
the doped graphene of the first cap layer is directly on the top surface of the conductive wire.
